(19) United States
(12) Patent Application Publication
(10) Pub. No.: US 2007/0232002 A1
(43) Pub. Date: Oct. 4, 2007

(54) Static random access memory using independent double gate transistors

(76) Inventor: Peter L. D. Chang, Portland, OR (US)

Correspondence Address: TROP PRUNER & HU, PC, 1616 S. VOSS ROAD, SUITE 750, HOUSTON, TX, 77057-2631, US

(21) Appl. No.: 11/392,524

(22) Filed: Mar. 29, 2006

(51) Int. Cl. H01L 21/336

(52) U.S. Cl. 438/283

(57) ABSTRACT

A static random access memory may use independent double gate transistors to form the pull up transistors. The other transistors of the memory are not formed of independent double gate transistors. In some embodiments, a reduced layout size may be achieved. In addition, in some embodiments, it is not necessary to form separately created polysilicon strips to form the two transistors. Finally, in some embodiments, the need for end caps may be eliminated.

### BACKGROUND

This invention relates generally to static random access memories.

A static random access memory or SRAM may use six transistors. Certain relationships are required among those transistors. One requirement results in jogs and a layout of diffusions or gates which are difficult to pattern at sizes below 100 nanometers. In addition, gate end caps or end-to-end space are key limiters for static random access memory cell area reduction.

Generally, the smaller the memory that may be formed, the lower the cost of the memory. This is because more actual cells can be formed in the same space on the integrated circuit wafer. Reduced size may sometimes also result in increased speed.

### BRIEF DESCRIPTION OF THE DRAWINGS

FIG. 1 is a partial, greatly enlarged layout view of one embodiment of the present invention;

FIG. 2 is a circuit depiction of the embodiment shown in FIG. 1;

FIG. 3 is a circuit diagram corresponding to FIG. 2 showing the read bias conditions in accordance with one embodiment of the present invention;

FIG. 4 is a circuit diagram corresponding to FIG. 2 showing the bias conditions for writing a one to a zero in accordance with one embodiment of the present invention;

FIG. 5 is an enlarged, cross-sectional view of one embodiment of the present invention at an early stage of manufacture in accordance with one embodiment of the present invention;

FIG. 6 is an enlarged, cross-sectional view corresponding to FIG. 5 at a subsequent stage of manufacture in accordance with one embodiment of the present invention;

FIG. 7 is an enlarged, cross-sectional view corresponding to FIG. 6 at a subsequent stage of manufacture in accordance with one embodiment of the present invention;

FIG. 8 is an enlarged, cross-sectional view corresponding to FIG. 7 at a subsequent stage of manufacture in accordance with one embodiment of the present invention;

FIG. 9 is an enlarged, cross-sectional view corresponding to FIG. 8 at a subsequent stage of manufacture in accordance with one embodiment of the present invention;

FIG. 10 is an enlarged, cross-sectional view corresponding to FIG. 9 at a subsequent stage of manufacture in accordance with one embodiment of the present invention;

FIG. 11 is an enlarged, cross-sectional view corresponding to FIG. 10 at a subsequent stage of manufacture in accordance with one embodiment of the present invention;

FIG. 12 is an enlarged, cross-sectional view corresponding to FIG. 11 at a subsequent stage of manufacture in accordance with one embodiment of the present invention;

FIG. 13 is an enlarged, cross-sectional view corresponding to FIG. 12 at a subsequent stage of manufacture in accordance with one embodiment of the present invention;

FIG. 14 is an enlarged, cross-sectional view corresponding to FIG. 13 at a subsequent stage of manufacture in accordance with one embodiment of the present invention;

FIG. 15 is an enlarged, cross-sectional view corresponding to FIG. 14 at a subsequent stage of manufacture in accordance with one embodiment of the present invention; and

FIG. 16 is a system schematic diagram for one embodiment.

### DETAILED DESCRIPTION

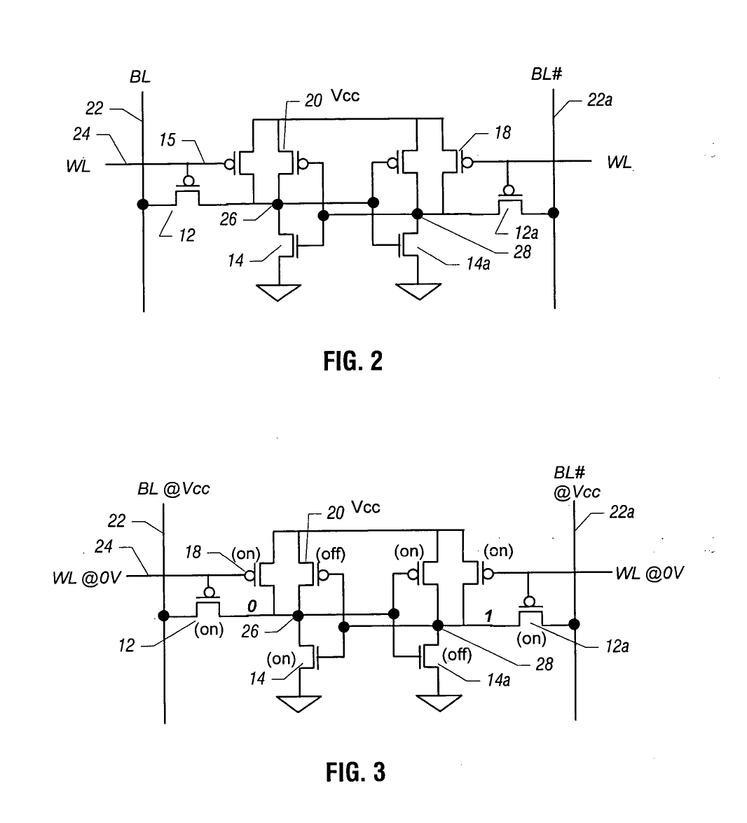

Referring to FIG. 2, a static random access memory (SRAM) 10, in accordance with one embodiment of the present invention, may include independent double gates as the pull up transistors 18 and 20. The independent double gate transistors or I-gates have two gates disposed on opposite sides of the channel, each gate being capable of being independently controlled. As one result of using independent double gate transistors as the pull up transistors, in some embodiments, separate pieces of poly may not be needed, in some embodiments, to form the transistors 18 and 20. In addition, issues with gate end cap and end-to-end space may be overcome in some embodiments. Finally, by making the other transistors, such as the pull down transistors 14, 14a and pass gates 12, 12a non-independent double gate transistors, the independent double gate transistors 18 and 20 may be made inherently weaker than the other transistors.

In one embodiment, the SRAM cell uses six sub 100 nanometer transistors. The six transistors may include two pass gates 12, 12a, two pull down transistors 14, 14a, and two pull up transistors 18 and 20. In one embodiment, a single diffusion width and single gate length cell layout may be used with a four diffusion pitch cell width and a two poly pitch cell height. The pass gate, pull up and pull down transistors may have the same diffusion width and gate length in one embodiment.

The pass gate, being PMOS, is inherently weaker than an NMOS pull down transistor of the same size. In one embodiment, the pass gates and pull down transistors may be tri-gate devices. Since both the pass gates and pull up transistors are PMOS, their relative strengths are determined by their respective diffusion widths of their conducting channels. In the case where the pass gates are tri-gates and the pull up transistors are dual gates, the pass gates may be inherently stronger than the pull up transistors. The relative strengths can be further tuned with the top and side diffusion areas of the tri-gates.

Generally, the pull down transistors 14, 14a may be stronger than the pass gate transistors 12, 12a and the pass gate transistors 12, 12a may be stronger than the pull up transistors 18, 20.

The pull up transistors 18 and 20 may be approximated by a pair of PMOS transistors, assuming independent operations of the front and back channels. This approximation may not be valid for devices with fully depleted or floating bodies. However, it provides a schematic sufficient for general discussion of the cell operation.

In the standby mode, the word line 24 is deactivated and the voltage on the word line 24 may be biased to the supply voltage V_{cc}. The pass gate transistors 12, 12a are turned off in this bias condition. The back gate BG of the pull up transistor 18 is at the off voltage and the pull up device 20 is controlled by the front gate, which is at the voltage of the internal node. The cell holds the voltages of the internal nodes as in a standard static random access memory.

During the read operation, the bias condition is shown in FIG. 3. The bitline (BL) 22 and the bitline bar 22a are biased at the supply voltage V_{cc} in one embodiment. The word lines 24 are biased at zero volts. The BG pull up device 18 effectively strengthens the pass gate 12 since both the bitline 22 and bitline bar 22a are biased at the supply voltage V_{cc}. The cell may remain stable since the NMOS pull down transistor 14 is naturally stronger than the pass gate transistor 12. The relative strengths of PMOS and NMOS transistors may be adjusted to provide read stability if necessary. In one embodiment, the silicon diffusion may be 90 nm wide on all three sides of the surface. The independent double gate transistors 18 and 20 may be 90 nanometers wide and the pass gate 12 and pull down devices 14 and 14a may be 270 nanometers wide in one embodiment. However, the devices can be scaled down to 50 nanometers for both diffusion width and height in another embodiment. In another embodiment the top surface may not have the same width as the sidewalls so that the relative strengths of independent double gate and trigate transistors may be adjusted.

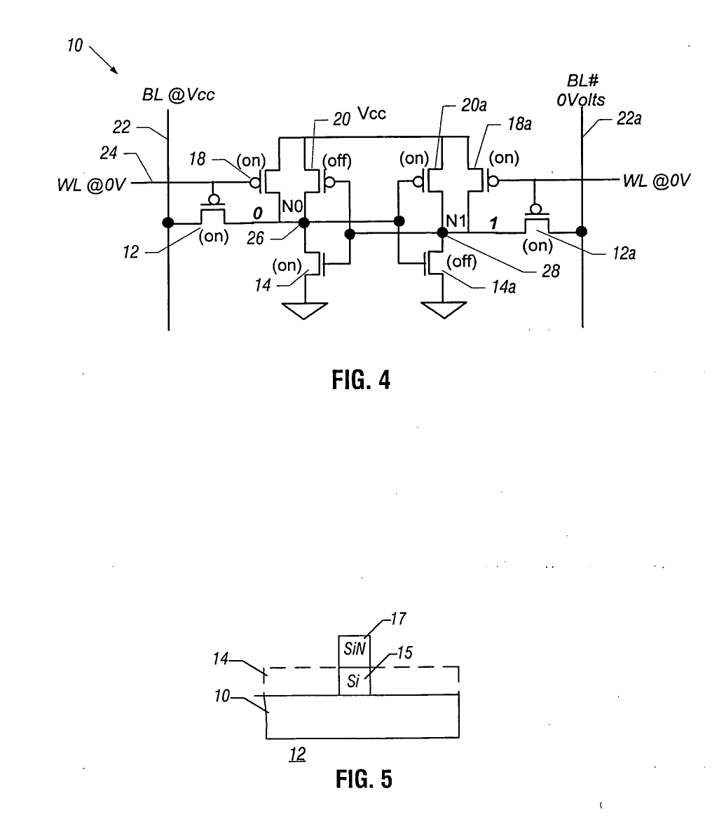

The write one to zero operation may be accomplished with the bias conditions shown in FIG. 4 in one embodiment. There, the bitline 22 is at the supply voltage and the bitline bar 22a is at zero volts, while the word line 24 is also at zero volts. This bias turns on pull up transistor 18, pull down transistor 14, and pass gate 12. The transistors 20 and 14a are initially off. Since pass gate 20a is stronger than the pull up transistors 18a and 20a, the voltage at N1 will be pulled down to the voltage of bitline bar 22a at “0.” As the voltage N1 is lowered, the pull down transistor 14 can be turned off and the floating gate of the pull up transistor 20 can be turned on, raising the voltage at N0 to V_{cc}. The high voltage at N0 then turns on pull down transistor 14a and turns off the floating gate pull up transistor 20a, which further pulls down the N1 voltage to 0, changing the internal state from “0” to “1.” A tradeoff between read and write margins can be made by adjusting the relative strengths between the pass gate and the pull up transistor, for example, by increasing the diffusion width and reducing the height.

The diffusion contacts and gate contacts can be printed separately. Since the gate contacts do not need to go down to the diffusion level, the distance between gate contacts and diffusion contacts may be determined by alignment tolerances between the two in some embodiments.

In tri-gate transistors, the gate forms adjacent three sides of a channel region. The tri-gate transistors, particularly when used with a high dielectric constant gate insulator and metal gate, can substantially improve the speed and performance of integrated circuits.

In some embodiments of the present invention, the pull up transistors 18 and 20 may be made of independent double gate transistors. Other devices may be formed as either planar transistors or tri-gate transistors in some embodiments.

A number of configurations for I-gate or independent double gate transistors have been proposed. One exemplary embodiment of a double gate transistor is described in the following discussion. It is provided not by way of limitation, but merely to illustrate one way of forming an independent double gate transistor. Other process formation techniques and other independent double gate transistor designs may also be adopted.

In one embodiment, the independent double gate transistors may be fabricated on an oxide layer 10 which is formed on a semiconductor substrate, such as the silicon substrate 12, as shown in FIG. 5. The transistor bodies are fabricated from a monocrystalline silicon layer 14 (shown in dotted lines in FIG. 5) disposed on layer 10. This silicon-on-insulator (SOI) substrate is well known in the semiconductor industry with the layer 14 disposed on the layer 10.

By way of example, the SOI substrate may be fabricated by bonding the oxide layer 10 and a silicon layer 14 onto the substrate 12. Then, the layer 14 may be planarized so that it is relatively thin. This relatively thin, low body effect layer may be used to form the bodies of active devices. Other techniques are known for forming an SOI substrate including, for instance, the implantation of oxygen into a silicon substrate to form a buried oxide layer.

The layer 14 may be selectively ion implanted with a p-type dopant in the regions where n channel devices are to be fabricated. The layer 14 may be selectively ion implanted with an n-type dopant in those regions where p channel devices are fabricated. This is used to provide the relatively light doping typically found in the channel of metal oxide semiconductor (MOS) devices fabricated in a complementary metal oxide semiconductor (CMOS) integrated circuit.

The I-gate transistor may be fabricated, with the described process, as either p channel or n channel devices. The doping of the channel regions of the transistors may be done at other points in the process flow.

In the processing for one embodiment, a protective oxide (not shown) may be disposed on the silicon layer 14, followed by the deposition of a silicon nitride layer. The nitride layer may be masked and patterned to define a plurality of silicon nitride insulating members 17 shown in FIG. 5. Then the underlying silicon layer 14 may be etched in alignment with this member 17, resulting in the silicon body 15.

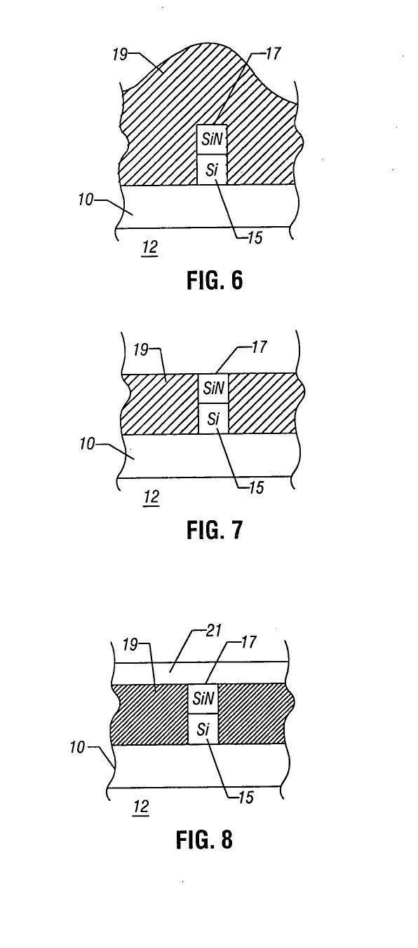

Next, as shown in FIG. 6, a sacrificial layer 19 may be deposited over the stack, including the insulative member/silicon body 17/15 and on the oxide layer 10. In one embodiment, this layer 19 is a polysilicon layer 15-200 nanometers thick. Other materials may be used for the sacrificial layer 19.

In some embodiments, the material used for the sacrificial layer 19 protects the channel regions of the I-gate devices from ion implantation during the formation of the source and drain regions. And, the sacrificial layer may be selectively removable so as not to significantly impact the integrity of an interlayer dielectric formed around the sacrificial layer after patterning to form sacrificial gate members.

In some embodiments, the sacrificial layer 19 is planarized prior to patterning and etching the sacrificial gate defining members. In other cases, the sequence may be reversed.

The sacrificial layer 19 may be deposited so it completely covers the stacks. The sacrificial layer 19 may be subsequently patterned and etched to form sacrificial gate defining members. The gate defining members temporarily occupy the regions where the independent double gate transistors will eventually be formed.

In embodiments using tri-gate transistors, the independent double gate transistor structures may be masked at this stage and process steps for making unique features of tri-gate transistors may be implemented.

After depositing the sacrificial layer 19, as shown in FIG. 6, the sacrificial layer 19 may be planarized as shown in FIG. 7. Planarization may be accomplished using conventional chemical mechanical polishing (CMP), a reactive ion etch, or other techniques. In embodiments where chemical mechanical processing is used, that process may be a timed polish or the insulative members 17 may function as polish stops, as two examples. Upon exposure to the upper surfaces of the members 17, the system may respond by terminating the polishing process immediately, terminating after a pre-determined time, or terminating after performing an over polish processing step. In other embodiments, the polish or etch back process may alternatively terminate at some point prior to exposing the insulative member 17.

Following planarization, the sacrificial layer 19 may now have a more planar topography, facilitating the patterning and etching of the gate defining members in some embodiments. In addition, the resulting etch features may have reduced aspect ratios, in some embodiments, thereby facilitating improved step coverage of subsequently deposited films.

As shown in FIG. 8, an optional hard mask 21 may now be formed over the planarized sacrificial layer 19. In one embodiment, the hard mask may be a silicon oxynitride layer. Alternatively, the hard mask can include other materials, such as silicon nitride and silicon-rich-silicon-nitride, to mention two examples. The hard mask may provide a uniform surface onto which the resist can be patterned in some embodiments.

Instead of the exposed surface area including areas of silicon nitride via insulative member 17 in areas of polysilicon corresponding to sacrificial layer 19, the hard mask may provide a single surface onto which the resist may be patterned. This may reduce resist adhesion problems in some embodiments. In addition, it may function as a protective masking layer during subsequent etch processes to define the gate defining members, thereby allowing the use of thinner resists so that increasingly smaller feature sizes can be patterned in some cases. Therefore, the hard mask may have a thickness that sufficiently protects the sacrificial layer during subsequent etch processes to define the gate defining members.

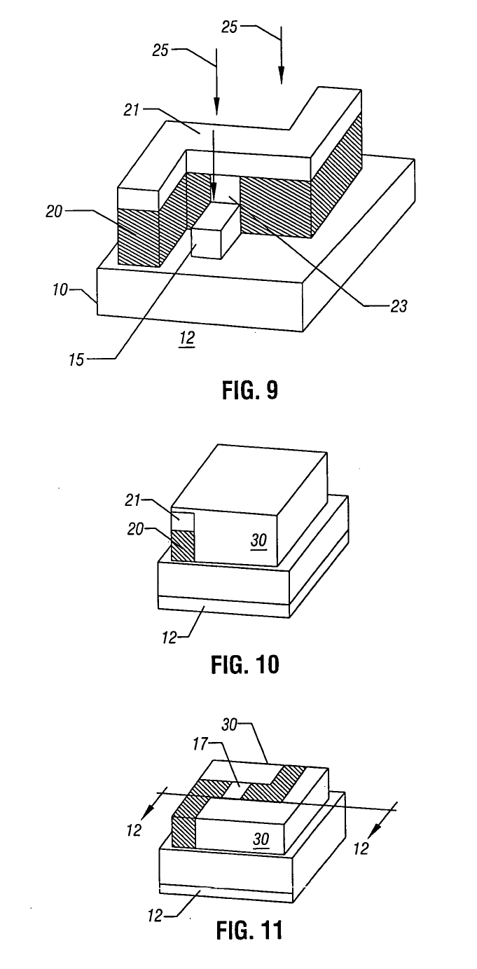

Next, the sacrificial hard mask layers may be patterned and etched in some embodiments. As a result, remaining portions of the sacrificial layer 19 may form gate defining members, shown as member 20 in FIG. 9. The member 20 may occupy the region in which two gates for the I-gate transistor are fabricated, as well as areas where contact and/or connections can be made. Because the sacrificial layer may be thinner than it otherwise would have been and because its topography has less variation associated with it, in some embodiments, the sacrificial layer etched to form the gate defining members may be less prone to problems with underetch and overetch. This may reduce the occurrence of over etch and under etch-related defects and can also reduce cycle time and improve manufacturability in some cases.

As shown in FIG. 9, portions of the insulative member 17, not covered by the gate defining member 20, may be etched, exposing portions of the underlying silicon body 15. Then, as indicated by the arrows 25, the silicon body 15, to the extent it is not covered by the member 20, can be ion implanted to form source and drain regions for the I-gate transistor. Separate implantation steps may be used for the p channel and n channel devices with protective or masking layers being used to prevent separate implantation of the source and drains for p channel and n channel devices.

Additionally, spacers may be formed to allow more lightly doped source and drain regions to be implanted, adjacent the channel region. More heavily doped source and drain regions may be spaced from the channel region.

Turning now to FIG. 10, an interlayer dielectric (ILD) 30 may be formed over the insulative layer 10, gate defining member 20, and silicon body 15. The ILD 30 may be formed adjacent the sides of the member 20 and can be used to form a trench that allows the inlay of metal once the gate defining members are removed in some embodiments. The ILD 30 may, for example, be a chemical vapor deposited silicon dioxide layer.

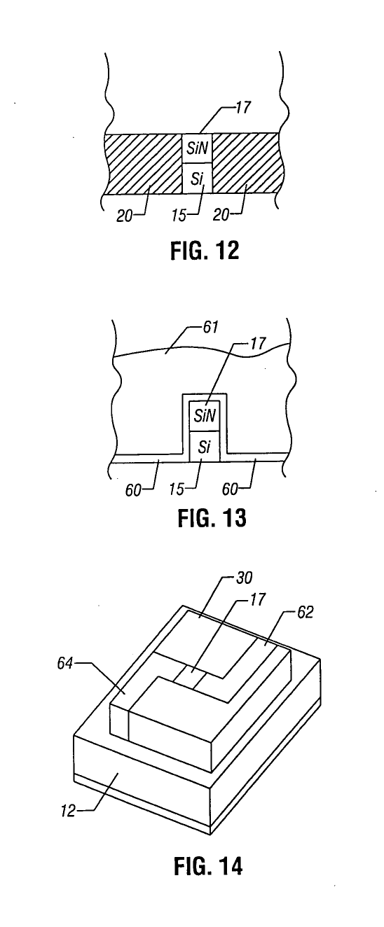

The ILD 30 may then be planarized, for example, using a CMP process to remove portions of the ILD and portions of the hard mask 21 overlying the insulative member 17, exposing the upper surfaces of the insulative member 17, as shown in FIGS. 11 and 12. The upper surface of the member 17 may be flush with the upper surface of the ILD 30 and the upper surface of the member 20 in some embodiments. A wet etch can be used to etch away the sacrificial member 20 and expose the sidewalls of silicon body 15 for gate dielectric and gate electrode. For areas where tri-gate transistors are desired, the SiN can be removed prior to the removal of the sacrificial member 20. In these areas, all three sides of silicon body 15 will be exposed to gate dielectric and gate electrode deposition, resulting in a tri-gate transistor.

A gate dielectric layer 60 may be formed on and around each silicon body 15, as shown in FIG. 13 for an I-gate transistor. A gate dielectric may be deposited such that it covers the top surface of the silicon body 15 and the insulative member 17, as well as on the opposite sidewalls of each of the semiconductor bodies. This gate dielectric has a high dielectric constant in some embodiments. For example, the gate dielectric may be a metal oxide dielectric such as HfO₂, ZrO, or other high dielectric constant dielectrics. A high dielectric constant dielectric film may be formed by well known techniques such as chemical vapor deposition, atomic layer deposition, or other known techniques. Alternatively, the gate dielectric can be a grown dielectric. In one embodiment, the gate dielectric layer 60 is a silicon dioxide film grown with a wet/dry/wet oxidation process. For example, the silicon dioxide film may be grown to a thickness of between 5 and 50 Angstroms.

Next, as shown in FIG. 13, a metal gate electrode layer 61 may be formed over the gate dielectric layer 60. The gate electrode layer 61 may be formed by blanket deposition of a suitable gate electrode material. In one embodiment, a gate electrode material comprised of a metal film, such as tungsten, tantalum, titanium, or nitrides and alloys thereof. For example, the n channel, I-gate transistor may have a workfunction in the range of 4.0 to 4.6 eV. For the p channel transistor, a workfunction of 4.6 to 5.2 eV may be used. Consequently, for substrates with both n channel and p transistors, separate gate electrode deposition processes may be used.

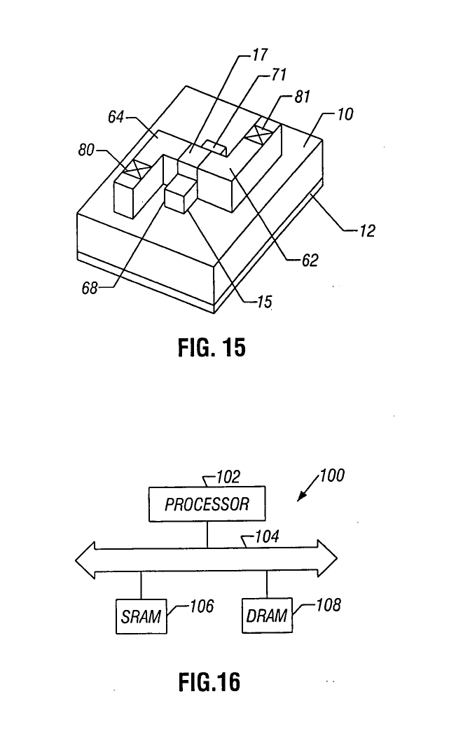

The layer 61 may be planarized, for example, using chemical mechanical planarization and such planarization may continued until at least the upper surface of the insulative member 17 is exposed, as shown in FIGS. 14 and 15. FIG. 15 is shown without an interlayer dielectric 30 for clarity. This may be done to reduce the possibility that the gate electrode spans the member 17. Otherwise, the gates in the independent double gate transistor may be shorted together. As can be seen from FIG. 14, there are two independent gates 62 and 64 for the independent double gate transistor spaced apart by the insulator 17.

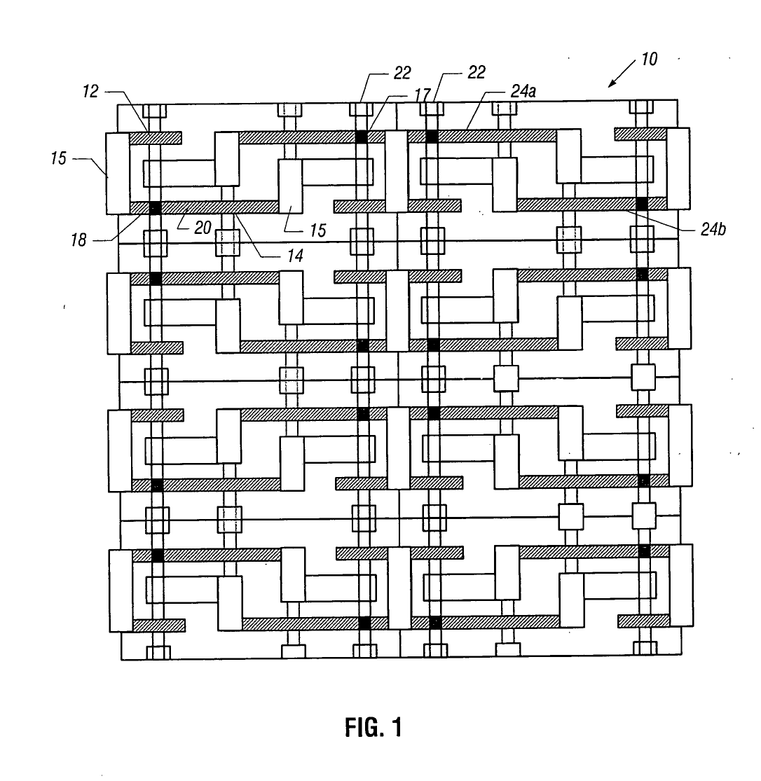

Finally, referring to FIG. 1, the word line 24 may be formed of the top poly 24a and the bottom poly 24b. The bitlines 22 extend transversely. Each double gate transistor 18 and 20 may be formed on either side of an insulator 17. Thus, each double gate transistor may be formed of the same portion of the top poly 24a for example. The double gate pull up transistors 18 and 20 may be coupled to the pass gate 12 by a contact 15. The contact 15 may be formed in a layer above the polysilicon level and below the metal one. The pull down devices 14, 14a may be formed as indicated. Thus, in each case, the source and drain may be formed in the bitline diffusion 22, above and below the insulator 17.

The use of double gate transistors may have several advantages in some embodiments. In some embodiments, the independent double gate transistors take up less space. In addition, they may be weaker than other non-independent double gate transistors (such as planar or tri-gate transistors used for the pull down and/or pass gate transistors), resulting in the desired relationship of relative strength for static random access memories. This effect may be achieved without any extra processing in some embodiments. In addition, the poly end cap between neighboring cells may be eliminated. Finally, the need to form two independent pieces of polysilicon to fabricate the pull up transistors 18 and 20 may be avoided in some embodiments. The two pieces of polysilicon may be naturally separated using the independently controlled double gate process and the insulator 17.

Finally, referring to FIG. 16, a processor-based system 100 may be, for example, a computer server, a desktop computer, a laptop computer, a personal media player, a video device, a digital camera, or any of a variety of other such devices. In some embodiments, the system 100 includes one or more processors 102 and on-die SRAMs. The processor or processors 102 may include multiple processors packaged within one single integrated circuit package or multiple processors formed in one single integrated circuit die. The processor 102 may be coupled by a bus 104 to the static random access memory 10, already described. Also coupled to the bus 104 may be a dynamic random access memory 108 in accordance with one embodiment of the present invention. In other embodiments, the dynamic random access memory 108 may not be needed and other components may be provided. Thus, only a simple system 100 is shown. No particular architecture is intended to be depicted thereby. The present invention is not limited to any particular system architecture. Moreover, a wide variety of other system components may be included.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a static random access memory using an independent double gate transistor as a pull up device and a non-independent double gate transistor as a pass gate coupled to said pull up device.

2. The method of claim 1 including forming a memory including pull up and pull down transistors and pass gate transistors, and forming only said pull up transistors as independent double gate transistors.

3. The method of claim 2 including forming the pull down transistors and pass gate transistors as tri-gate transistors.

4. The method of claim 1 including eliminating end caps.

5. The method of claim 2 including forming said pull up transistors as PMOS devices.

6. The method of claim 5 including forming said pull down transistors of NMOS devices.

7. The method of claim 6 including forming said pass gates as PMOS devices.

8. The method of claim 1 including forming a six transistor cell having a size less than 100 nanometers.

9. The method of claim 2 including forming all the pull up and pull down transistors of the same gate length and diffusion width.

10. The method of claim 9 including forming all of said transistors of the same gate length and diffusion width.

11. A static random access memory comprising:
an independent double gate pull up transistor; and
a non-independent double gate pass gate coupled to said pull up transistor.

12. The memory of claim 11 including pull up, pull down, and pass gate transistors forming a cell, only said pull up transistors formed as independent double gate transistors.

13. The memory of claim 12 wherein said pull down and pass gate transistors are tri-gate transistors.

14. The memory of claim 11 without end caps.

15. The memory of claim 12 wherein said pull up transistors are PMOS devices.

16. The memory of claim 15 wherein said pull down transistors are NMOS devices.

17. The memory of claim 16 wherein said pass gates are PMOS transistors.

18. The memory of claim 11 wherein said memory has a six transistor cell and a cell size less than 100 nanometers.

19. The memory of claim 12 wherein the pull up and pull down transistors have the same gate length and diffusion width.

20. The memory of claim 19 wherein said pull up, pull down, and pass gate transistors all have the same gate length and diffusion width.

21. A system comprising:
a processor;
a static random access memory coupled to said processor, said static random access memory including an independent double gate pull up transistor and a non-independent double gate pass transistor coupled to said pull up transistor; and
a dynamic random access memory coupled to said processor.

22. The system of claim 21 wherein said static random access memory including pull up, pull down, and pass gate transistors, only said pull up transistors formed as independent double gate transistors.

23. The system of claim 22 wherein said pull down and pass gate transistors are tri-gate transistors.

24. The system of claim 21 wherein said static random access memory does not include end caps.

25. The system of claim 22 wherein said pull up transistors are PMOS devices, said pull down transistors are NMOS devices, and said pass gates are PMOS devices.
